(19) United States
(12) Patent Application Publication
(10) Pub. No.: US 2023/0345699 A1
(43) Pub. Date: Oct. 26, 2023

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: Xiaojie LI, Hefei (CN)

(21) Appl. No.: 18/152,193

(22) Filed: Jan. 10, 2023

Related U.S. Application Data
(63) Continuation of application No. PCT/CN2022/108345, filed on Jul. 27, 2022.

(30) Foreign Application Priority Data
Apr. 26, 2022 (CN) 202210447115.X

(51) Int. Cl. H10B 12/00

(52) U.S. Cl. CPC H10B 12/05; H10B 12/03; H10B 12/30

(57) ABSTRACT

A semiconductor structure and a method for manufacturing the same are provided. The method includes: providing a substrate with a first area and a second area; forming a stack structure on the substrate; and forming a plurality of columns of silicon pillar structures and support structures in the stack structure located on the second area, in which the plurality of columns of silicon pillar structures are arranged at intervals in a first direction; each column of silicon pillar structure includes a plurality of silicon pillars that are arranged at intervals and are parallel to the substrate; the plurality of silicon pillars in the plurality of columns of silicon pillar structures are distributed in a plurality of layers; and any adjacent silicon pillars are connected by the support structure.

### CROSS-REFERENCE TO RELATED APPLICATIONS

This application is a U.S. continuation application of International Application No. PCT/CN2022/108345, filed Jul. 27, 2022, which claims priority to Chinese Patent Application No. 202210447115.X, filed Apr. 26, 2022. International Application No. PCT/CN2022/108345 and Chinese Patent Application No. 202210447115.X are incorporated herein by reference in their entireties.

### BACKGROUND

A Dynamic Random Access Memory (DRAM) is a semiconductor memory capable of writing and reading data at a high speed and randomly, and is widely applied to a data storage device or apparatus. The DRAM is composed of a plurality of repeated storage units. Each storage unit generally includes a capacitor and a transistor. The capacitor stores data information. The transistor controls the reading of the data information in the capacitor. The capacitor is generally vertically arranged on a substrate. With the continuous improvement of the integration degree of a semiconductor structure, the capacitor has a large aspect ratio, which is not conducive to the manufacturing of the capacitor.

In order to improve the integration degree of the semiconductor structure, in the related art, the arrangement mode of the capacitor is converted from vertical arrangement into horizontal arrangement. However, the horizontally arranged capacitor causes the deformation of the semiconductor structure easily, thereby affecting the yield of the semiconductor structures.

### SUMMARY

The disclosure relates to the technical field of semiconductors, and in particular, to a semiconductor structure and a method for manufacturing the same.

A first aspect of the embodiments of the disclosure provides a method for manufacturing a semiconductor structure, which includes that: a substrate is provided. The substrate includes a first area and a second area connected to the first area.

A stack structure is formed on the substrate.

A plurality of columns of silicon pillar structures and support structures are formed in the stack structure located on the second area. The plurality of columns of silicon pillar structures are arranged at intervals in a first direction. Each column of silicon pillar structure includes a plurality of silicon pillars that are arranged at intervals and are parallel to the substrate. The plurality of silicon pillars in the plurality of columns of silicon pillar structures are distributed in a plurality of layers. The support structure is configured to connect any adjacent silicon pillar.

A capacitor structure surrounding each of the silicon pillars is formed.

In a second aspect of the embodiments of the disclosure, there is provided a semiconductor structure. The semiconductor structure is obtained by the method for manufacturing a semiconductor structure provided in the first aspect.

### BRIEF DESCRIPTION OF THE DRAWINGS

In order to more clearly illustrate the embodiments of the disclosure or the technical solutions in the related art, the drawings used in the description of the embodiments or the related art will be briefly described below. It is apparent that the drawings in the following description are some embodiments of the disclosure, and other drawings can be obtained by those skilled in the art according to these drawings without any creative work.

FIG. 1 illustrates a process flowchart of a method for manufacturing a semiconductor structure provided by the embodiments of the disclosure.

FIG. 2 illustrates a schematic structural diagram after a stack structure is formed in the method for manufacturing a semiconductor structure provided by the embodiments of the disclosure.

FIG. 3 illustrates a sectional view in direction A-A in FIG. 2.

FIG. 4 illustrates a schematic structural diagram after mask layers is formed in the method for manufacturing a semiconductor structure provided by the embodiments of the disclosure.

FIG. 5 illustrates a sectional view in direction A-A in FIG. 4.

FIG. 6 illustrates a schematic structural diagram after a first photoresist layer is formed in the method for manufacturing a semiconductor structure provided by the embodiments of the disclosure.

FIG. 7 illustrates a sectional view in direction A-A in FIG. 6.

FIG. 8 illustrates a schematic structural diagram after strips are formed in the method for manufacturing a semiconductor structure provided by the embodiments of the disclosure.

FIG. 9 illustrates a sectional view in direction A-A in FIG. 8.

FIG. 10 illustrates a schematic structural diagram after a second sacrificial layer is formed in the method for manufacturing a semiconductor structure provided by the embodiments of the disclosure.

FIG. 11 illustrates a sectional view in direction A-A in FIG. 10.

FIG. 12 illustrates a schematic structural diagram after a second photoresist layer is formed in the method for manufacturing a semiconductor structure provided by the embodiments of the disclosure.

FIG. 13 illustrates a sectional view in direction A-A in FIG. 12.

FIG. 14 illustrates a schematic structural diagram after second trenches are formed in the method for manufacturing a semiconductor structure provided by the embodiments of the disclosure.

FIG. 15 illustrates a sectional view in direction A-A in FIG. 14.

FIG. 16 illustrates a schematic structural diagram after third trenches are formed in the method for manufacturing a semiconductor structure provided by the embodiments of the disclosure.

FIG. 17 illustrates a sectional view in direction A-A in FIG. 16.

FIG. 18 illustrates a schematic structural diagram after an insulating layer is formed in the method for manufacturing a semiconductor structure provided by the embodiments of the disclosure.

FIG. 19 illustrates a sectional view in direction A-A in FIG. 18.

FIG. 20 illustrates a schematic structural diagram after a support structure is formed in the method for manufacturing a semiconductor structure provided by the embodiments of the disclosure.

FIG. 21 illustrates a sectional view in direction A-A in FIG. 20.

FIG. 22 illustrates a schematic structural diagram after a photoresist strip is formed in the method for manufacturing a semiconductor structure provided by the embodiments of the disclosure.

FIG. 23 illustrates a sectional view in direction A-A in FIG. 22.

FIG. 24 illustrates a schematic structural diagram after a second sacrificial layer is removed in the method for manufacturing a semiconductor structure provided by the embodiments of the disclosure.

FIG. 25 illustrates a sectional view in direction A-A in FIG. 24.

FIG. 26 illustrates a schematic structural diagram after a first sacrificial layer is removed in the method for manufacturing a semiconductor structure provided by the embodiments of the disclosure.

FIG. 27 illustrates a sectional view in direction A-A in FIG. 26.

FIG. 28 illustrates a schematic structural diagram after a capacitor structure is formed in the method for manufacturing a semiconductor structure provided by the embodiments of the disclosure.

FIG. 29 is an enlarged schematic diagram of area B in FIG. 26.

FIG. 30 illustrates a schematic structural diagram after a first interconnection layer is formed in the method for manufacturing a semiconductor structure provided by the embodiments of the disclosure.

FIG. 31 illustrates a sectional view in direction A-A in FIG. 30.

FIG. 32 illustrates a schematic structural diagram after part of the first interconnection layer and part of the capacitor structure are removed in the method for manufacturing a semiconductor structure provided by the embodiments of the disclosure.

FIG. 33 illustrates a sectional view in direction A-A in FIG. 32.

FIG. 34 illustrates a schematic structural diagram after a support structure is removed in the method for manufacturing a semiconductor structure provided by the embodiments of the disclosure.

FIG. 35 illustrates a sectional view in direction A-A in FIG. 34.

FIG. 36 illustrates a schematic structural diagram after an epitaxial layer is formed in the method for manufacturing a semiconductor structure provided by the embodiments of the disclosure.

FIG. 37 illustrates a sectional view in direction A-A in FIG. 36.

FIG. 38 illustrates a schematic structural diagram after a silicon oxide layer is formed in the method for manufacturing a semiconductor structure provided by the embodiments of the disclosure.

FIG. 39 illustrates a sectional view in direction A-A in FIG. 38.

FIG. 40 illustrates a schematic structural diagram after a second interconnection layer is formed in the method for manufacturing a semiconductor structure provided by the embodiments of the disclosure.

FIG. 41 illustrates a sectional view in direction A-A in FIG. 40.

FIG. 42 illustrates a schematic structural diagram of a semiconductor structure provided by the embodiments of the disclosure.

### DETAILED DESCRIPTION

As described in the BACKGROUND, in a related art, there is a problem of deformation of silicon pillars during manufacturing a horizontal capacitor structure. The inventors have found that the main reason for this problem is that: when a plurality of silicon pillars distributed in an array are manufactured, there is no support structure between adjacent silicon pillars, which causes tilting or bending of silicon pillars under the action of their own weight, thereby reducing the yield of semiconductor structures.

Based on the abovementioned technical problem, in the semiconductor structure and the method for manufacturing the same provided by the embodiments of the disclosure, the support structures are also formed while silicon pillars in a plurality of layers and a plurality of columns are formed, and any adjacent silicon pillars are connected by using the support structure, so that the silicon pillar can be prevented from deforming due to its own weight, improving the strength of the plurality of columns of silicon pillars, thereby preventing the silicon pillar from tilting or bending during the manufacturing of a capacitor structure, and thus improving the yield of the semiconductor structures.

In order to make the abovementioned objectives, features, and advantages of the embodiments of the disclosure more apparent and easier to understand, the technical solutions in the embodiments of the disclosure will be clearly and completely described below with reference to the drawings in the embodiments of the disclosure. It is apparent that the described embodiments are only part rather than all embodiments of the disclosure. Based on the embodiments in the disclosure, all other embodiments obtained by those of ordinary skill in the art without creative efforts shall fall within the scope of protection of the disclosure.

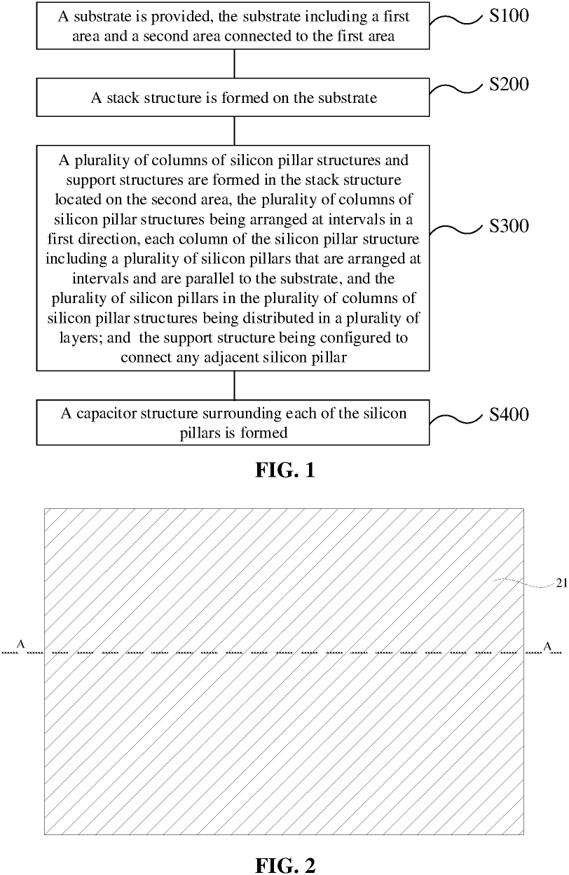

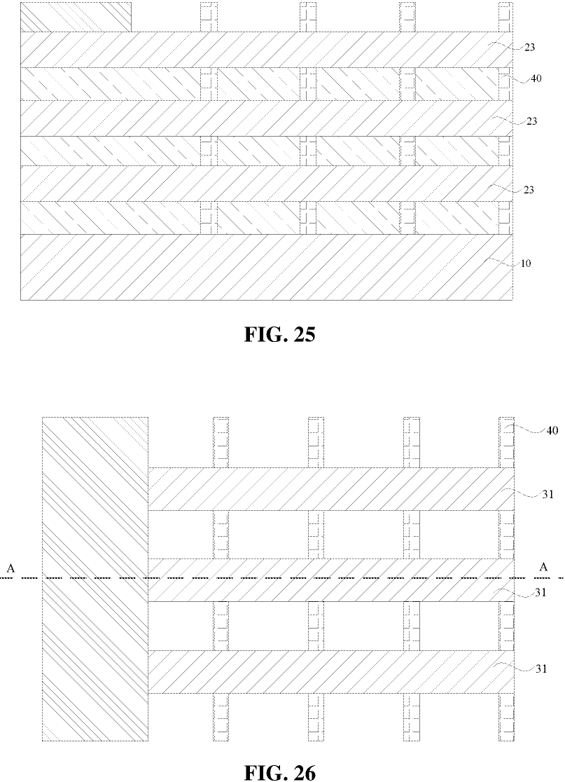

FIG. 1 illustrates a flowchart of a method for manufacturing a semiconductor structure provided by the embodiments of the disclosure. FIG. 2 to FIG. 41 illustrate schematic diagrams of various stages of the method for manufacturing a semiconductor structure provided by the embodiments of the disclosure. The method for manufacturing a semiconductor structure is introduced in detail below with reference to FIG. 2 to FIG. 41.

Referring to FIG. 1, the embodiments of the disclosure provide a method for manufacturing a semiconductor structure, which includes the following steps.

At S100: a substrate is provided. The substrate includes a first area and a second area connected to the first area.

Referring to FIG. 2 and FIG. 3, the substrate 10 provides support for supporting a film layer thereon. The substrate 10 may be a semiconductor substrate. Exemplarily, the substrate 10 may be a silicon substrate, a germanium substrate, a silicon carbide (SiC) substrate, a silicon germanium (SiGe) substrate, a Germanium on Insulator (GOI) substrate, or a Silicon on Insulator (SOI) substrate, etc.

The substrate 10 includes a first area and a second area connected to the first area. The first area is configured to form the semiconductor devices, such as a transistor, a word line, and a bit line. The second area is configured to form a capacitor structure.

It is to be noted that the first area is connected with the second area. It can be understood that the first area and the second area are arranged side by side. Reference is continued to be made to FIG. 3 for the structure thereof. It can also be understood that the first area is arranged around the second area. In order to express the first area and the second area clearly, it is advisable to define area L1 in FIG. 3 as the first area and area L2 in FIG. 3 as the second area.

At S200: a stack structure is formed on the substrate.

Exemplarily, referring to FIG. 3 again, initial silicon layers 21 and first initial sacrificial layers 22 that are stacked alternately are formed on the substrate 10. That is, a plurality of initial silicon layers 21 and a plurality of first initial sacrificial layers 22 are formed on the substrate 10. The plurality of initial silicon layers 21 and the plurality of first initial sacrificial layers 22 constitute the stack structure 20.

The plurality of initial silicon layers 21 and the plurality of first initial sacrificial layers 22 are sequentially stacked and alternately arranged in a direction perpendicular to the substrate 10. The first initial sacrificial layers 22 are arranged on the substrate 10. The numbers of the initial silicon layers 21 and the first initial sacrificial layers 22 may be set according to actual requirements.

In some possible implementation modes, the initial silicon layers 21 and the first initial sacrificial layers 22 may be formed through a deposition process. The deposition process may include a Chemical Vapor Deposition (CVD) process, a Physical Vapor Deposition (PVD) process, or an Atomic Layer Deposition (ALD), etc.

In some another possible implementation modes, the first initial sacrificial layers 22 is formed by an Epitaxy (EPI) process. Thus, the problem of lattice mismatch between the first initial sacrificial layer 22 and the initial silicon layer 21 can be avoided. The material of the first initial sacrificial layer 22 includes SiGe, so that the first initial sacrificial layer 22 and the initial silicon layer 21 have a great etching selectivity ratio, so as to selectively remove the first sacrificial layer by a subsequent process, and reduce the etching of the silicon layer.

In addition, the first initial sacrificial layer 22 also provides certain support for the initial silicon layer 21 to ensure the normal progress of a process for manufacturing the semiconductor structure.

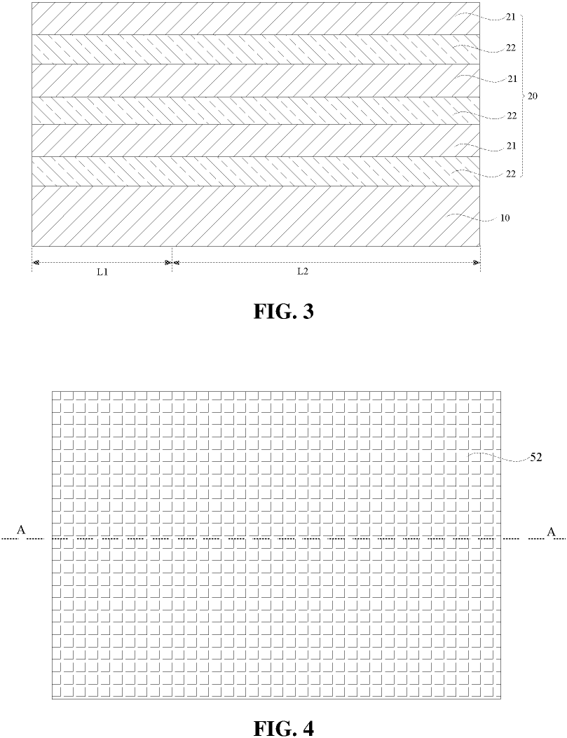

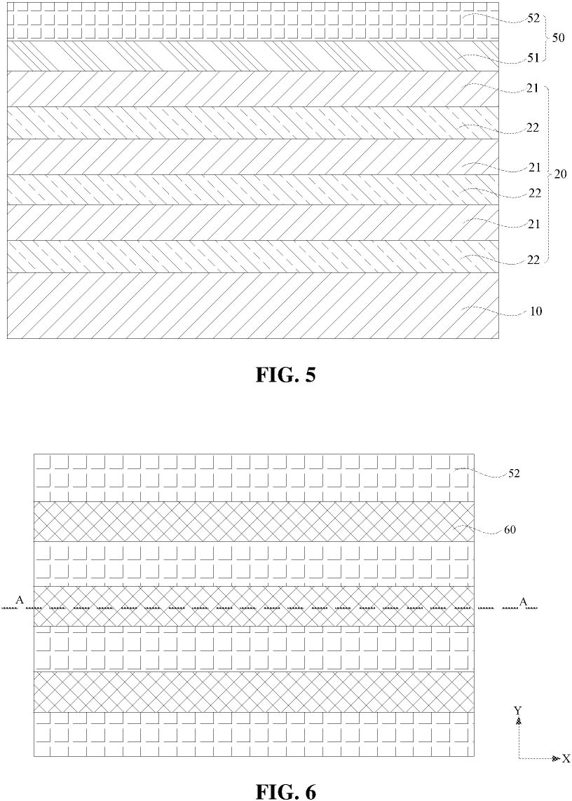

Referring to FIG. 4 and FIG. 5, in order to facilitate the formation of a plurality of columns of silicon pillar structures and support structures in the stacked structure located on the second area. In the embodiment, an initial mask layer 50 is formed on the stack structure 20. Thus, the stack structure 20 located on the second area is patterned with the initial mask layer 50 as a mask.

The initial mask layer 50 may be a single film layer or a laminated structure. When the initial mask layer 50 is a laminated structure, the initial mask layer 50 may include a first initial mask layer 51 and a second initial mask layer 52. The first initial mask layer 51 is arranged on the stack structure 20, and the second initial mask layer 52 is arranged on the first initial mask layer 51. Thus, the mask pattern can be transferred into the second initial mask layer 52 first, then, the first initial mask layer 51 is etched with the second initial mask layer 52 with the mask pattern as a mask, so as to transfer the mask pattern onto the first initial mask layer 51, and finally, the stack structure 20 is etched with the first initial mask layer 51 with the mask pattern as the mask. Thus, the accuracy in a process of transferring the mask pattern can be improved, and thereby the manufacturing accuracy of the semiconductor structure can be improved.

The material of the first initial mask layer 51 may include silicon oxide, but is not limited thereto. The material of the second initial mask layer 52 may include silicon nitride, but is not limited thereto.

At S300: a plurality of columns of silicon pillar structures and support structures are formed in the stack structure located on the second area. The plurality of columns of silicon pillar structures are arranged at intervals in a first direction. Each column of silicon pillar structure includes a plurality of silicon pillars that are arranged at intervals and are parallel to the substrate. The plurality of silicon pillars in the plurality of columns of silicon pillar structures are distributed in a plurality of layers. The support structure is configured to connect any adjacent silicon pillar.

In a possible example, at S310: part of the stack structure is etched to form a plurality of first trenches arranged at intervals in the first direction. The stack structure is divided into a plurality of columns of strips by the plurality of first trenches. Each column of strip includes silicon layers and first sacrificial layers stacked alternately. The length direction of the first trenches is perpendicular to the first direction. The structure is as shown in FIG. 8 and FIG. 9.

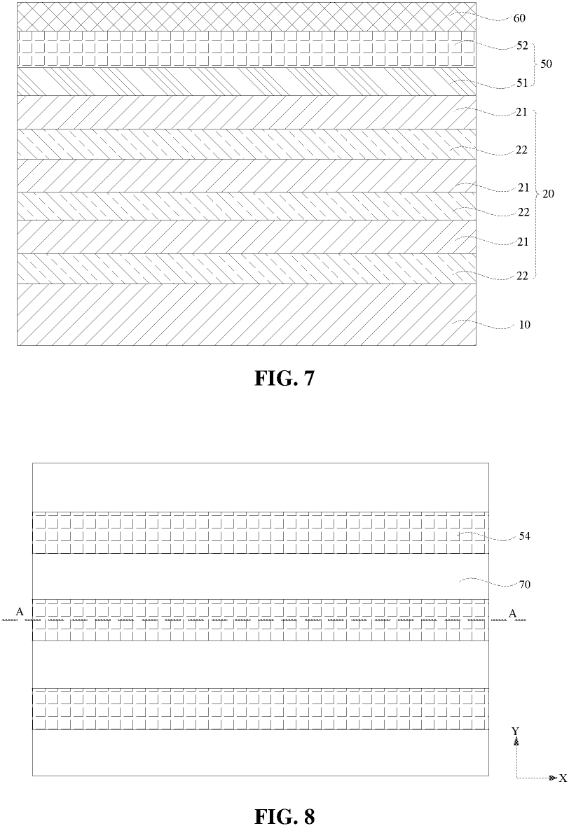

Exemplarily, referring to FIG. 6 and FIG. 7, a first photoresist layer 60 may be formed on the initial mask layer 50. For example, the first photoresist layer 60 may be formed on the second initial mask layer 52 by using a coating process, after that, a first mask pattern is formed in the first photoresist layer 60 by means of exposing, developing, or etching. The first mask pattern includes a plurality of first protrusions and a first opening located between adjacent first protrusions. The plurality of first protrusions are arranged at intervals in the first direction, and each first protrusion extends in the second direction. The second direction is perpendicular to the first direction.

The first direction is the Y direction in FIG. 6, and the second direction is the X direction in FIG. 6. Thus, it can be ensured that the extending direction of the subsequently formed silicon pillar is parallel to the substrate, so that a three-dimensionally stacked storage unit can be formed. Compared with a two-dimensional storage unit in the related art, more storage units may be arranged in an effective area, so that the storage capacity of the semiconductor structure is improved.

Referring to FIG. 8 and FIG. 9, the initial mask layer 50 and the stack structure 20 exposed in the first openings are removed by dry etching or wet etching. The remaining stack structure 20 constitutes a plurality of columns of strips 25. The plurality of columns of strips 25 are arranged at intervals in the first direction. A first trench 70 is formed between two adjacent columns of strips 25, and each first trench 70 extends in the second direction.

That is to say, the remaining first initial sacrificial layer 22 constitutes a first sacrificial layer 24, and the remaining initial silicon layer 21 constitutes a silicon layer 23, so that the each column of strip 25 includes silicon layers 23 and first sacrificial layers 24 that are stacked and arranged alternately. The remaining initial mask layer 50 forms a plurality of columns of mask layers 55. A plurality of columns of mask layers 55 and a plurality of columns of strips 25 are arranged in one-to-one correspondence. Each column of mask layers 55 includes a first mask layer 53 and a second mask layer 54 stacked and arranged alternately.

At S320: a second sacrificial layer is formed in each of the first trenches.

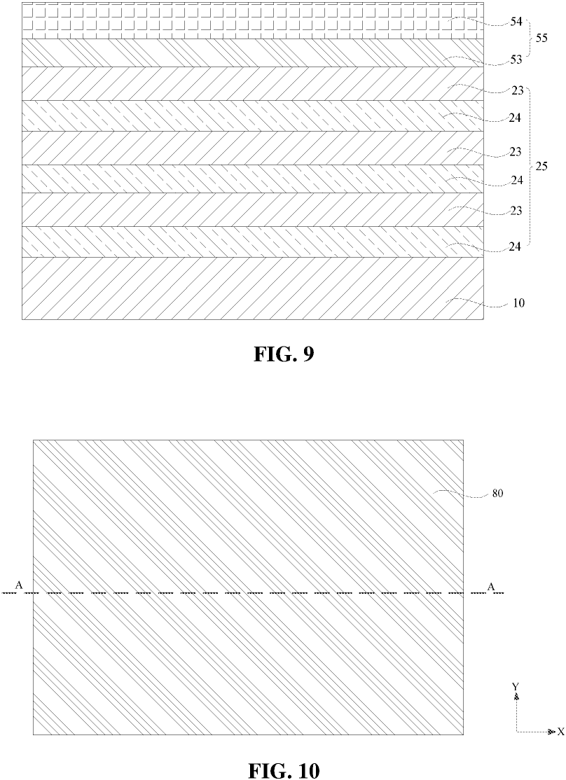

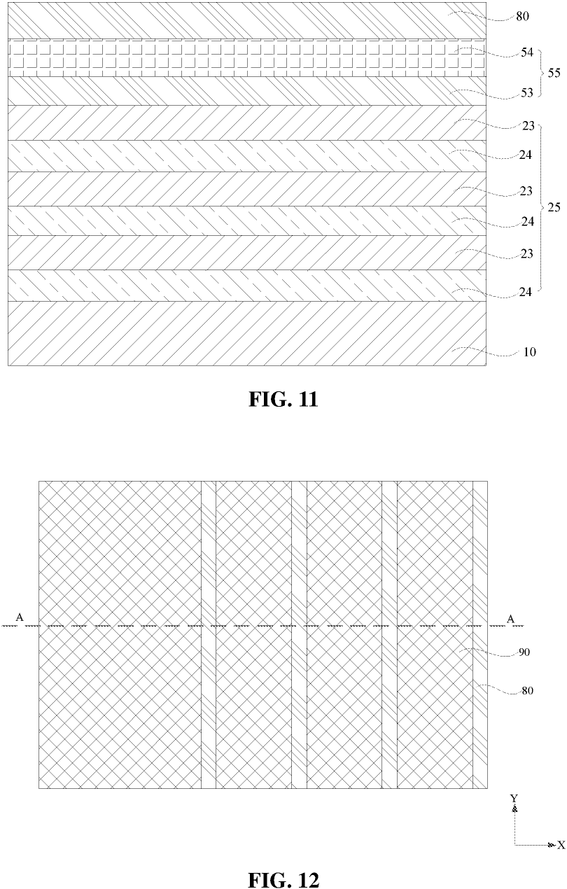

Referring to FIG. 10 and FIG. 11, a second sacrificial layer 80 is formed by depositing in the first trenches 70. The second sacrificial layer 80 further extends outside the first trench 70 and covers the top surfaces of a plurality of columns of mask layers 55 and a plurality of columns of strips 25.

Exemplarily, the second sacrificial layer 80 is formed in the first trenches 70 by the processes such as a Chemical Vapor Deposition (CVD) process, a Physical Vapor Deposition (PVD) process, or an Atomic Layer Deposition (ALD). The thickness direction of the second sacrificial layer 80 and the depth direction of the first trench 70 are the same and both are a direction perpendicular to the substrate 10.

In the embodiment, the material of the second sacrificial layer 80 includes silicon oxide, but is not limited thereto.

At S330: part of the second sacrificial layer is etched to form a plurality of second trenches in the second sacrificial layer. The second trenches expose part of the top surface of the substrate. Moreover, part of the first sacrificial layer is removed to form a plurality of third trenches arranged at intervals in the first sacrificial layer. The third trenches are communicated with the second trenches to form a filling area.

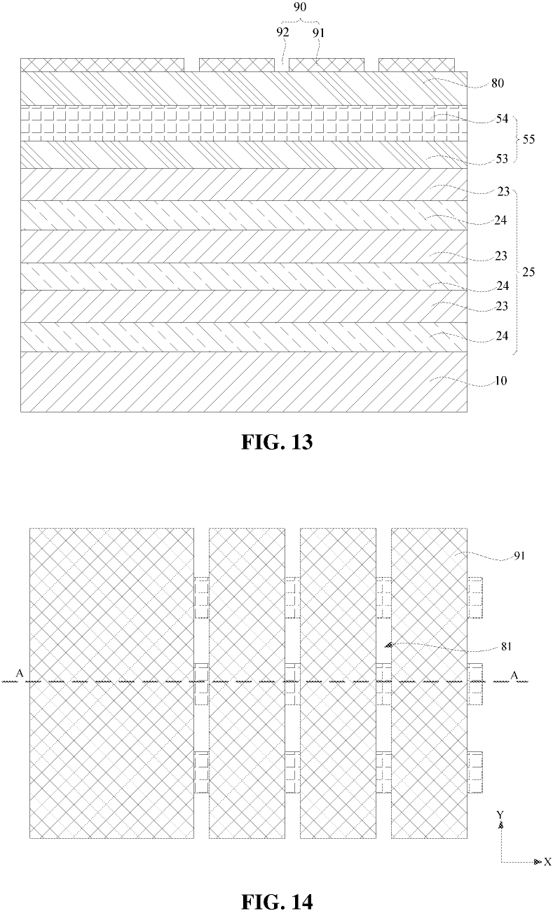

Exemplarily, referring to FIG. 12 and FIG. 13, a second photoresist layer 90 may be formed on the second sacrificial layer 80 by using a coating process. After that, a second mask pattern is formed in the second photoresist layer 90 by means of exposing, developing, or etching. The second mask pattern includes a plurality of second protrusions 91 and a second opening 92 located between adjacent second protrusions 91. The plurality of second protrusions 91 are arranged at intervals in the second direction, and each of the second protrusions 91 extends in the first direction. All of the second openings 92 are located above the second area, so as to prevent the second openings 92 from forming above the first area. Thus, it can be ensured that a plurality of columns of silicon pillar structures are formed above the second area, and one end of the plurality of columns of silicon pillar structures is allowed to be connected to the stack structure 20 retained above the first area, so as to provide support for the plurality of columns of silicon pillar structures, thereby improving the stability of the plurality of columns of silicon pillar structures.

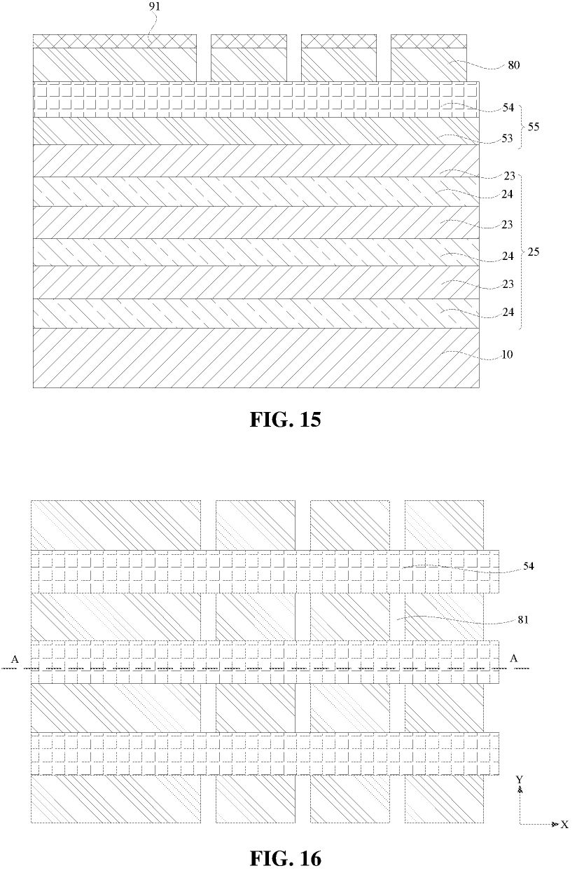

After that, referring to FIG. 14 and FIG. 15, the second sacrificial layer 80 exposed in the second openings 92 is removed by dry etching or wet etching, so as to form a plurality of second trenches 81 in second sacrificial layer 80. The depth direction of the second trenches 81 is perpendicular to the substrate 10, and the second trenches 81 expose part of the top surface of the substrate 10.

Taking the orientation shown in FIG. 14 as an example, a plurality of second trenches 81 are arranged in a plurality of rows and a plurality of columns. Each row includes a plurality of second trenches 81, and the plurality of second trenches 81 are arranged at intervals in the second direction.

In the first direction, side walls of each second trench 81 are opposite surfaces of adjacent columns of strips 25. Thus, each second trench 81 exposes part of the first sacrificial layer 24, so that part of the first sacrificial layer 24 can be selectively removed subsequently, which ensures the normal progress of a process for manufacturing the semiconductor structure.

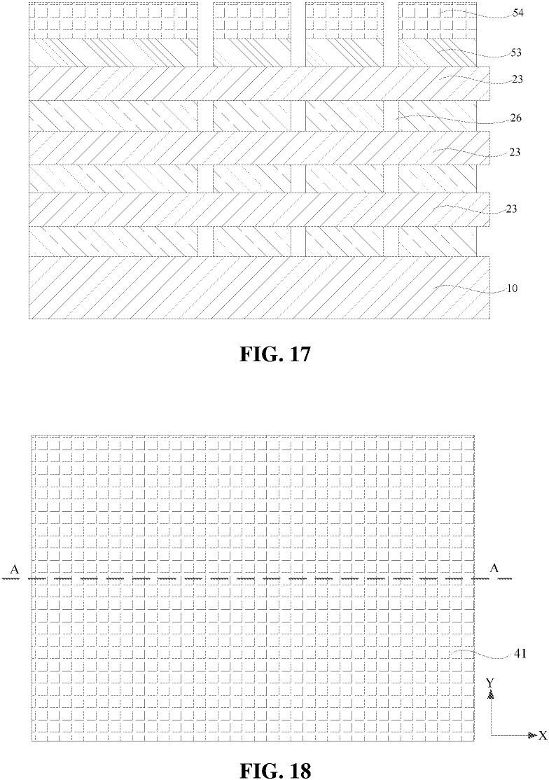

After that, referring to FIG. 16 and FIG. 17, the first sacrificial layers 24 exposed in the second trenches 81 is continued to be removed by dry etching or wet etching, so as to form third trenches 26 arranged at intervals in each of the first sacrificial layers 24. The third trenches 26 are communicated with the second trenches 81 to form a filling area. The depth direction of the third trenches 26 is the same as the first direction. The third trench 26 penetrates through the first sacrificial layer 24 in the first direction.

Finally, the second photoresist layer 90 and the second sacrificial layer 80 located on the mask layer 55 may be removed.

At S340: support structures are formed in the filling area. The support structure includes a plurality of support pillars arranged in a rectangular array. Each support pillar is configured to connect adjacent silicon pillars.

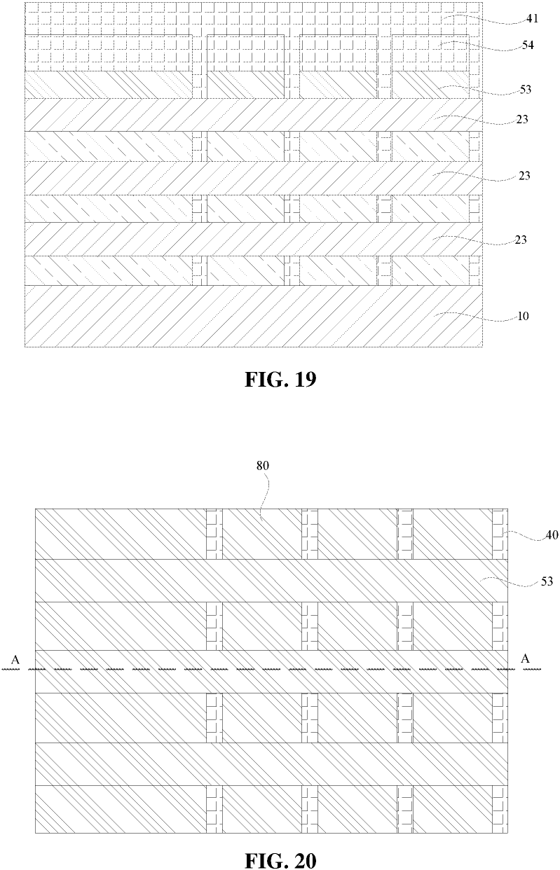

Exemplarily, referring to FIG. 18 and FIG. 19, an insulating layer 41 is formed by using a deposition process. The insulating layer 41 fills up the filling area and covers the top surfaces of the strips 25 and the mask layers 55. The materials of the insulating layer 41 and the second mask layer 54b may be the same, for example, the material of the insulating layer 41 includes silicon nitride.

After that, the insulating layer 41 located on the top surfaces of the strips 25 and the mask layers 55 is removed through a Chemical Mechanical Polishing (CMP) process, so as to expose the top surfaces of the mask layers 55.

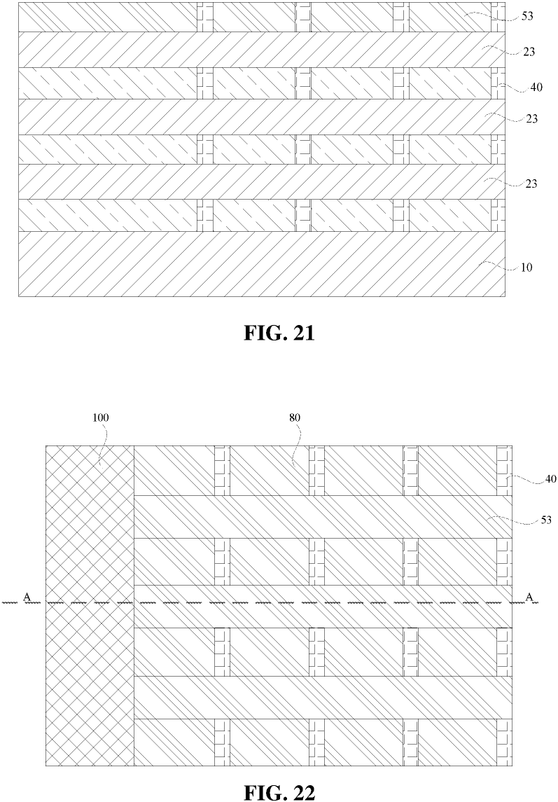

Referring to FIG. 20 and FIG. 21, part thickness of the mask layer 55 is continued to be removed by the CMP process. For example, the second mask layer 54 may be removed, and the first mask layer 53 located on the strip 25 is retained. The insulating layer 41 retained in the filling area constitutes the support structure 40. The support structure 40 may include a plurality of support pillars arranged in a rectangular arrange. The support pillars located in a row direction are configured to support adjacent silicon pillars in the first direction. The support pillars located in a column direction are configured to support adjacent silicon pillars in the third direction. Thus, the silicon pillars are supported in both the horizontal plane and the vertical plane, so as to be prevented them from deforming, thereby improving the yield of the semiconductor structures.

At S350, the remaining first sacrificial layer and the remaining second sacrificial layer located on the second area are removed to form a plurality of columns of silicon pillar structures.

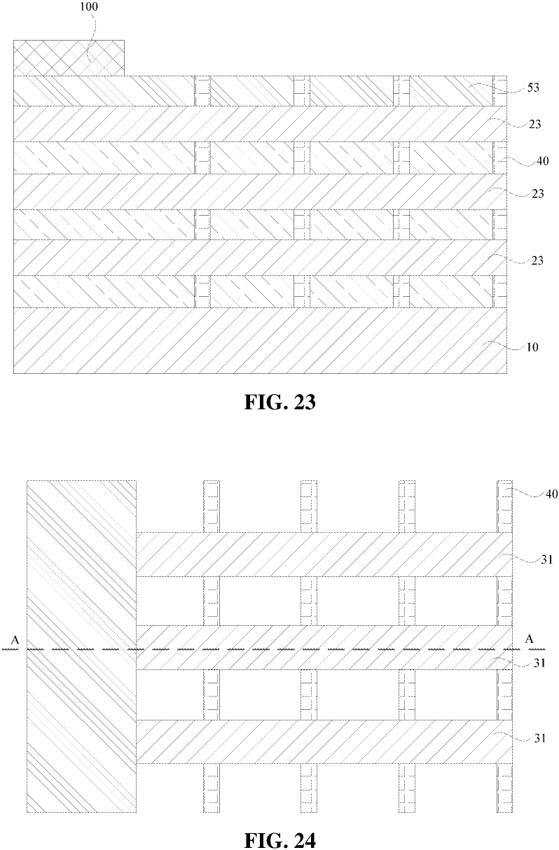

Exemplarily, referring to FIG. 22 and FIG. 23, a photoresist strip 100 is formed. The photoresist strip 100 is located on the first area, and the photoresist strip 100 extends in the first direction. The photoresist strip 100 extends in the direction perpendicular to the silicon pillar, that is, the photoresist strip 100 extends in the first direction.

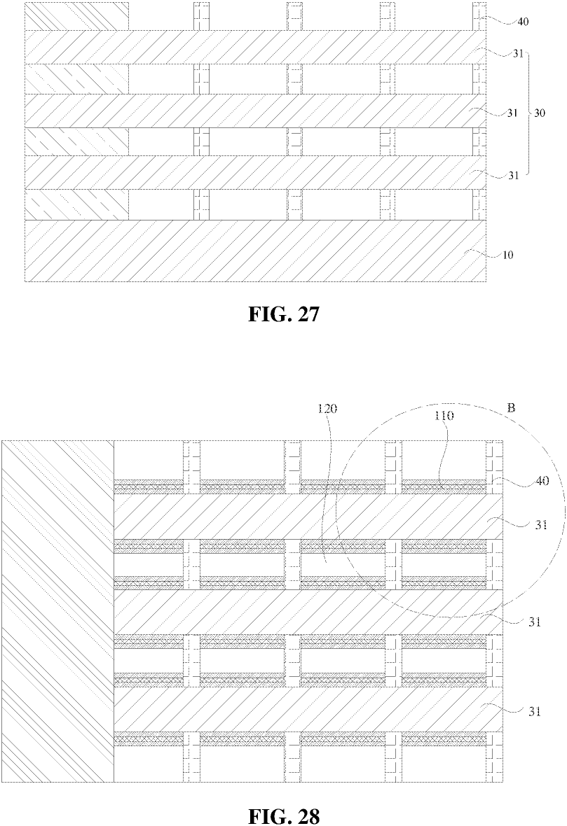

After that, referring to FIG. 24 and FIG. 27, the remaining first sacrificial layer 24 and the remaining second sacrificial layer 80 located on the second area are removed to form a plurality of columns of silicon pillar structures 30. For example, the second sacrificial layer 80 located between adjacent strips 25 may be removed first, and then the remaining first sacrificial layer 24 is removed.

It is to be noted that the silicon layer 23 located above the second area may be referred to as a silicon pillar 31, and the silicon layer 23 located above the first area is configured to form an active pillar. In addition, the remaining first mask layer 53 located on the silicon layer 23 also needs to be removed at this step.

At S400, a capacitor structure surrounding each of the silicon pillars is formed.

Exemplarily, referring to FIG. 28 and FIG. 29, a first electrode layer 111, a dielectric layer 112, and a second electrode layer 113 surrounding the silicon pillar 31 are formed on each of the exposed silicon pillars 31 in sequence. There is a first gap 120 between any adjacent second electrodes 113.

In an example, a metal with a certain thickness may be selectively formed on each of the silicon pillars 31 through a selective Conductive on Conductive (CoC) ALD process, so as to form a first electrode layer 111. Thus, the area defined by the silicon pillar 31 and the support structure 40 may be prevented from filling up with the metal, and thus it is avoided that part of the metal needs to be removed by an etching process, so that a process for manufacturing a capacitor structure can be simplified, thereby reducing the production cost of the process for manufacturing the semiconductor structure.

In the embodiment, the dielectric layer 112 has a high dielectric constant, so that the performance of the capacitor structure can be ensured. A material with a high-k dielectric constant may include hafnium oxide (HfO₂), hafnium silicon oxide (HfSiO₂), lanthanum oxide (LaO), zirconium oxide (ZrO₂), zirconium silicon oxide (ZrSiO₂), tantalum oxide (Ta₂O₅), titanium oxide (TiO₂), barium strontium titanium oxide (BaSrTiO₃), barium titanium oxide (BaTiO₃), strontium titanium oxide (SrTiO₃), lithium oxide (Li₂O), aluminum oxide (Al₂O₃), lead scandium tantalum oxide (PbScTaO), lead zinc niobate (PbZnNbO₃), or combinations thereof.

During forming the capacitor structure, by the provision of the support structure 40, the silicon pillar 31 may be supported in both the horizontal plane and the vertical plane, so that the bearing capacity of the silicon pillar 31 is improved, preventing the silicon pillar 31 i from deforming due to the pressure of the capacitor structure 110, thereby improving the yield of the semiconductor structures.

In some embodiments, after the step in which the capacitor structure surrounding each silicon pillar is formed, the method for manufacturing the semiconductor structure further includes the following operation.

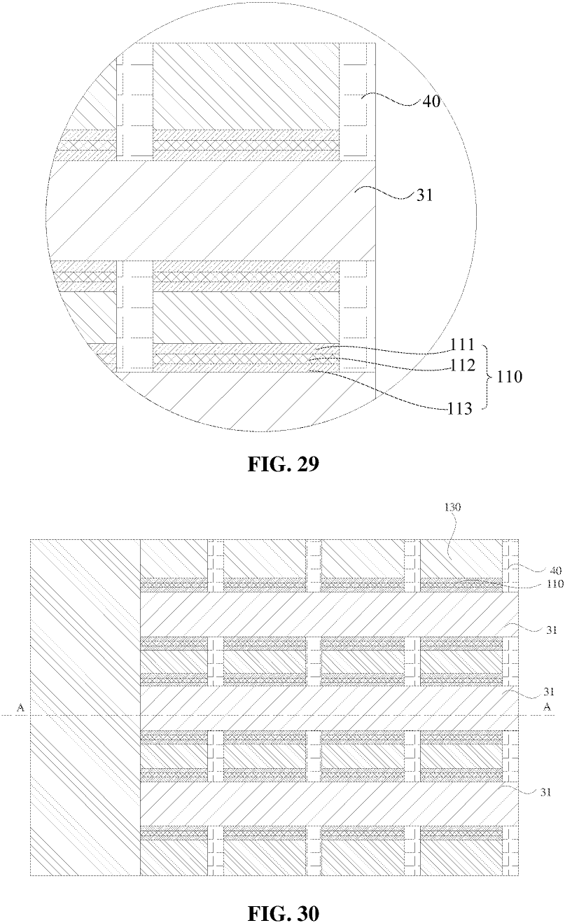

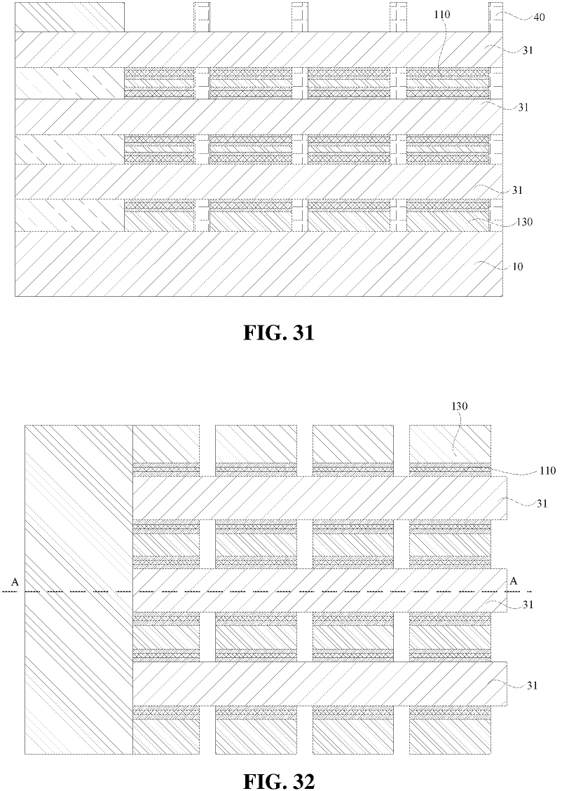

Referring to FIG. 30 and FIG. 31, a first interconnection layer 130 is formed by a deposition process. The first interconnection layer 130 wraps all of the capacitor structures 110 and fills up the first gaps 120. The material of the first interconnection layer 130 includes polysilicon.

The first interconnection layer is configured to connect the second electrode layers 113 of all capacitor structures together, so that all of the capacitor structures are arranged in parallel. Therefore, the capacitance of the semiconductor structure is the sum of the capacitances of all of the capacitor structures, and the total current after the capacitor structures are connected in parallel is equal to the sum of the current of the capacitor structures. Thus, the storage capacity of the semiconductor structure can be increased, and thus the performance of the semiconductor structure is improved.

After that, referring to FIG. 31 again, part of the first interconnection layer 130 and part of a capacitor structure 110 are removed by an etching liquid or an etching gas to expose the upper surface of the silicon pillar 31 located on the uppermost layer.

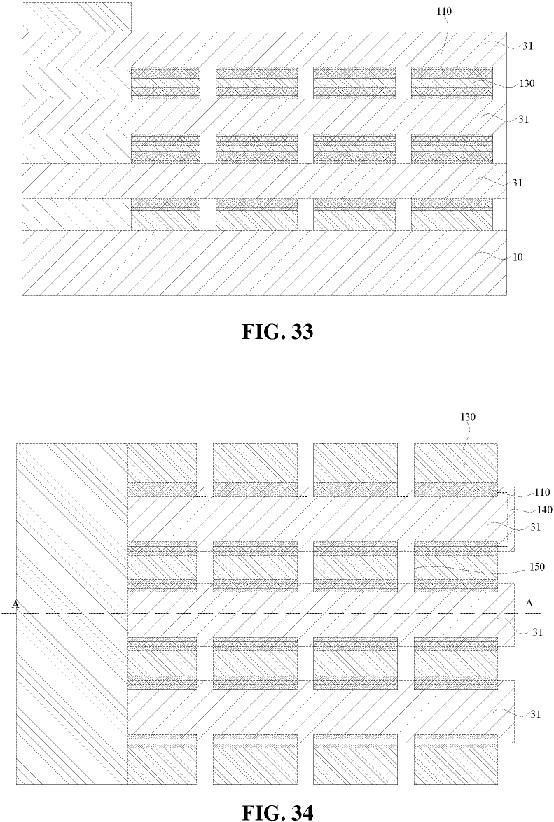

Referring to FIG. 32 and FIG. 33, the support structure 40 is continued to be removed by the etching liquid or etching gas to expose the filling area. That is to say, the second trenches and the third trenches are exposed.

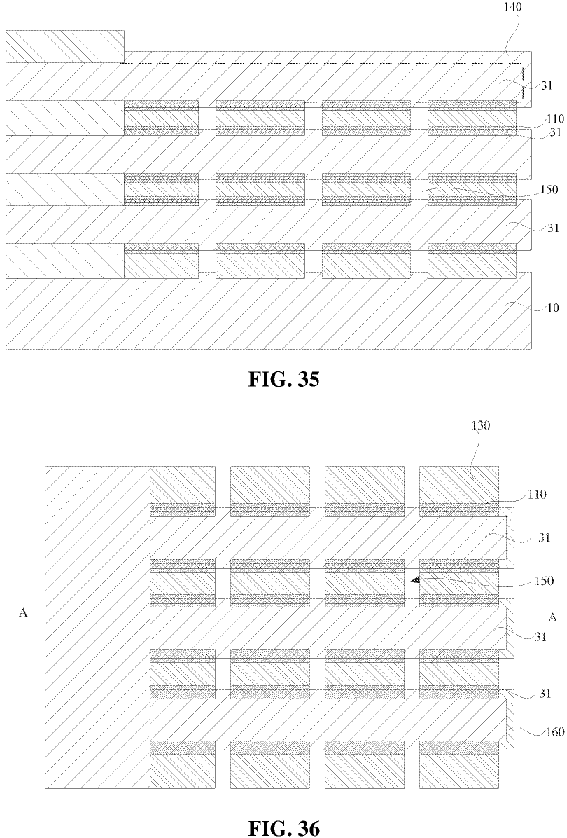

Referring to FIG. 34 and FIG. 35, an epitaxial layer 140 is formed on the surface of the silicon pillar 31 exposed in the filling area by an EPI process, and the epitaxial layer 140 defines a second gap 150 between adjacent capacitor structures 110. The material of the epitaxial layer includes silicon. It is to be noted that the epitaxial layer 140 is an area outside a dashed line.

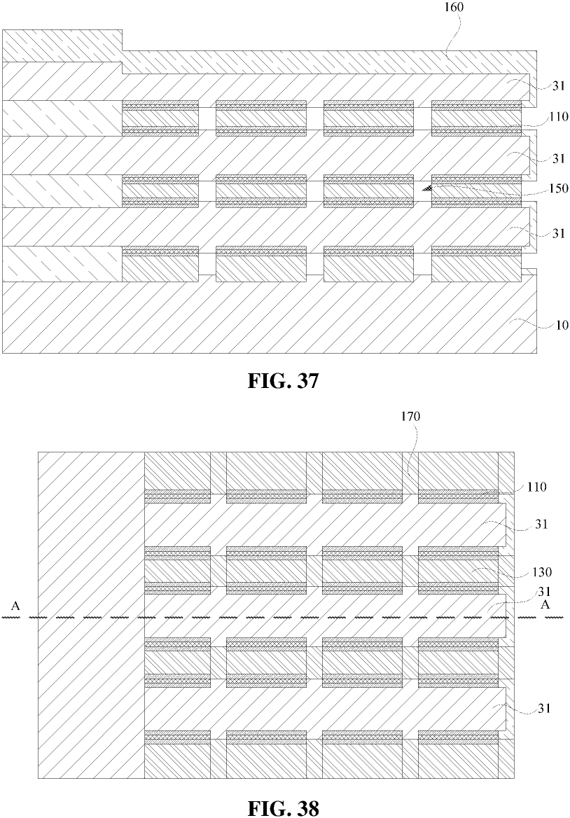

After that, referring to FIG. 36 and FIG. 37, after the step in which the epitaxial layer is formed by the EPI process, and before the step in which a second interconnection layer is formed, the method for manufacturing the semiconductor structure further includes: the epitaxial layer is oxidized, so that silicon in the epitaxial layer reacts with oxygen to form an oxide, so as to form an oxide layer 160.

In this step, the epitaxial layer may be oxidized directly by a high-temperature oxidization treatment process in deposition equipment. Thus, the volume of the second gap can be reduced, thereby better ensuring the electrical insulation between the plurality of capacitor structures located on a same silicon pillar.

In the embodiment, the thickness of the oxide layer is greater than that of the first electrode layer 111 and is less than the sum of the thicknesses of the first electrode layer 111 and the dielectric layer 112. Thus, a space can be reserved for the formation of the second interconnection layer 170, which ensures the interconnection of the second electrode layers 113 of the capacitor structures 110, and can also ensure the electrical insulation between the plurality of capacitor structures 110 located on the same silicon pillar 31.

It is to be noted that before the step in which the epitaxial layer is oxidized, the remaining first mask layer located on the first area may also be removed.

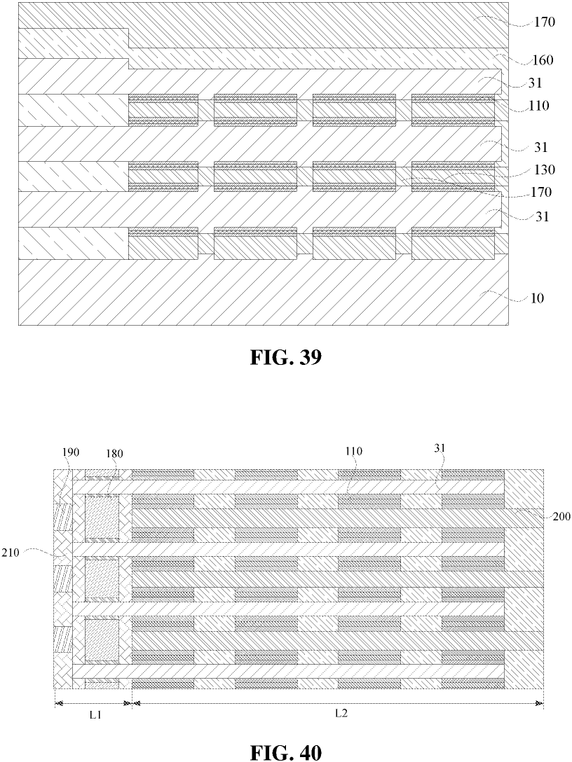

After the epitaxial layer 140 and the oxide layer 160 are formed, referring to FIG. 38 and FIG. 39, a second interconnection layer 170 is formed by a deposition process. The second interconnection layer fills up the second gap 150 and is connected to the first interconnection layer 130 to form an interconnection layer 200. The material of the second interconnection layer 170 includes polysilicon.

In the embodiment, the plurality of capacitor structures can be arranged in parallel through providing the first interconnection layer 130 and the second interconnection layer 170, so that the storage capacity of the capacitor structure is increased, and thus the performance of the semiconductor structure is improved.

In some embodiments, after the step in which the second interconnection layer is formed, the method for manufacturing the semiconductor structure further includes the following operation.

The first sacrificial layer in the stack structure located on the first area is removed. Exemplarily, a third photoresist layer (not shown in the drawings) is formed on the semiconductor structure located on the second area, and then the first sacrificial layer 24 located on the first area is removed by an etching gas or an etching liquid, so as to expose the silicon layer 23 located on the first area.

After that, an active pillar is formed in the silicon layer located on the first area. The active pillar includes a channel, and a source and a drain located on either side of the channel. The types of doping ions of the source and the drain may be the same, and the type of the doping ions of the channel may be different from that of the source. In an example, the doping ions of the channel may be P-type ions, and the doping ions of the source and drain may be N-type ions. In another example, the doping ions of the channel may be N-type ions, and the doping ions of the source and the drain may be P-type ions.

In the embodiment, the source, the drain, and the channel of the active pillar may be formed in segments through an ion diffusion or Plasma Doping System (PALD) process.

The process for forming the active pillar is not limited to the above description. The active pillar may also be formed by the following process steps: exemplarily, a fourth photoresist layer (not shown in the drawings) may be formed on the semiconductor structure located in the second area and part of the stack structure located in the first area. The fourth photoresist layer can block part of the stack structure and the semiconductor structure located on the second area. Then, part of the first sacrificial layer in the stack structure located on the first area is removed by dry etching or wet etching, so as to expose part of the silicon layer located on the first area. Then, part of the silicon layer located on the first area is exposed for ion doping by a plasma doping process, so as to form a channel. After that, the fourth photoresist layer is removed and a fifth photoresist layer covering the channel is formed. After that, the remaining first sacrificial layer is removed by dry etching or wet etching to expose the remaining silicon layer on the first area. After that, the remaining silicon layer located on the first area is exposed for ion doping by a plasma doping process, so as to form the source and drain. It is to be noted that a source and a drain may also be formed first by the abovementioned process, and then the channel is formed. The forming sequence of the source, the drain, and the channel of the active pillar is not specifically limited in the embodiment.

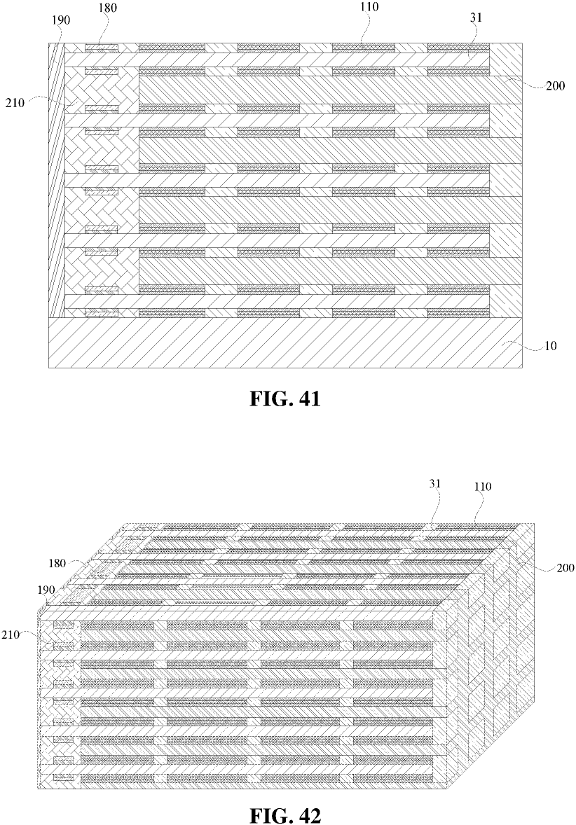

After the active pillar is formed, a plurality of bit lines 190 and a plurality of word lines 180 are formed on the first area. Reference can be made to FIG. 40 and FIG. 41 for the structure.

A plurality of bit lines 190 are arranged at intervals in the first direction. Each bit line 190 extends in the direction perpendicular to the substrate 10 and connects the active pillars in a same column. In an example, the bit line 190 may connect the sources of the active pillars in the same column. Correspondingly, the capacitor structure 110 may be connected to the drain of the active pillar. In another example, the bit line 190 may connect the drains of the active pillars in a same column. Correspondingly, the capacitor structure 110 may be connected to the source of the active pillar.

A plurality of word lines 180 are arranged at intervals in the direction perpendicular to the substrate 10. Each word line 180 extends in the first direction and connects the active pillars in a same layer. That is, each word line 180 is configured to connect the channels of the active pillars in the same layer.

In order to realize the insulation arrangement between adjacent bit lines 190 and word lines 180, the method for manufacturing a semiconductor structure further includes that: isolation layers 210 wrapping each bit line 190 and each word line 180 are formed on the first area. The material of the isolation layer 210 may include silicon oxide or silicon nitride.

The embodiments of the disclosure further provide a semiconductor structure. Reference is made to FIG. 42 for its structure. The semiconductor structure is prepared by the method in any of the abovementioned embodiments. Therefore, the semiconductor structure has the beneficial effects in the abovementioned embodiments. The embodiment will not be elaborated herein.

Various embodiments or implementation modes in the specification are described in a progressive mode. Each embodiment focuses on differences from other embodiments, and the same and similar parts of various embodiments may be referred to one another.

In the description of the specification, the description referring to the terms “one implementation mode ” “some implementation modes”, “schematic implementation mode”, “example”, “specific example”, or “some examples” etc. means that the specific features, structures, materials, or characteristics described in combination with the implementation modes or examples are included in at least one implementation mode or example of the disclosure.

In the specification, the schematic expression of the above terms does not necessarily mean the same implementation mode or example. Furthermore, the specific features, structures, materials, or characteristics described may be combined in an appropriate mode in any one or more implementation modes or examples.

Finally, it is to be noted that the foregoing embodiments are merely intended for describing the technical solutions of the disclosure, instead of limiting the disclosure. Although the disclosure is described in detail with reference to the foregoing embodiments, persons of ordinary skill in the art should understand that they may still make modifications to the technical solutions described in the foregoing embodiments or make equivalent replacements to some or all technical features thereof, without departing from the scope of the technical solutions of the embodiments of the disclosure.

1. A method for manufacturing a semiconductor structure, comprising:
providing a substrate comprising a first area and a second area connected to the first area;
forming a stack structure on the substrate;
forming a plurality of columns of silicon pillar structures and support structures in the stack structure located on the second area, wherein the plurality of columns of silicon pillar structures are arranged at intervals in a first direction, each column of silicon pillar structure comprises a plurality of silicon pillars that are arranged at intervals and are parallel to the substrate, and the plurality of silicon pillars in the plurality of columns of silicon pillar structures are distributed in a plurality of layers; and the support structure is configured to connect any adjacent silicon pillars; and
forming a capacitor structure surrounding each of the silicon pillars.

2. The method for manufacturing a semiconductor structure of claim 1, wherein the forming a plurality of columns of silicon pillar structures and support structures in the stack structure located on the second area comprises:
etching part of the stack structure to form a plurality of first trenches arranged at intervals in the first direction, wherein the stack structure is divided into a plurality of columns of strips by the plurality of first trenches, and each column of strip comprises silicon layers and first sacrificial layers stacked alternately, wherein a length direction of the first trenches is perpendicular to the first direction;
forming a second sacrificial layer in each of the first trenches;
etching part of the second sacrificial layer to form a plurality of second trenches in the second sacrificial layer, wherein the second trenches expose part of a top surface of the substrate; and removing part of a first sacrificial layer to form a plurality of third trenches arranged at intervals in each of the first sacrificial layers, wherein the third trenches are communicated with the second trenches to form a filling area;
forming the support structures in the filling area, wherein the support structure comprises a plurality of support pillars arranged in a rectangular array, wherein each of the support pillars is configured to connect adjacent silicon pillars; and
removing remaining first sacrificial layers and remaining second sacrificial layer located on the second area to form the plurality of columns of silicon pillar structures.

3. The method for manufacturing a semiconductor structure of claim 2, comprising: after the forming the stack structure on the substrate and before the forming a plurality of columns of silicon pillar structures and support structures in the stack structure located on the second area,
forming an initial mask layer on the stack structure, wherein the initial mask layer comprises a first initial mask layer and a second initial mask layer that are stacked, wherein the first initial mask layer is arranged on the stack structure.

4. The method for manufacturing a semiconductor structure of claim 3, wherein the etching part of the stack structure comprises:
forming a first photoresist layer with a first mask pattern on the second initial mask layer, wherein the first mask pattern comprises a plurality of first protrusions and a first opening located between adjacent first protrusions, wherein the plurality of first protrusions are arranged at intervals in the first direction, each of the first protrusions extends in a second direction, and the second direction is perpendicular to the first direction; and
removing the first initial mask layer and the stack structure exposed in the first opening, wherein the stack structure retained constitutes a plurality of columns of strips, the initial mask layer retained constitutes a plurality of columns of mask layers, and the plurality of columns of mask layers are in one-to-one correspondence with the plurality of columns of strips.

5. The method for manufacturing a semiconductor structure of claim 4, wherein the forming a second sacrificial layer in each of the first trenches comprises:
further forming the second sacrificial layer to cover top surfaces of the mask layers.

6. The method for manufacturing a semiconductor structure of claim 5, wherein the etching part of the second sacrificial layer comprises:
forming a second photoresist layer with a second mask pattern on the second sacrificial layer, wherein the second mask pattern comprises a plurality of second protrusions arranged at intervals and a second opening located between adjacent second protrusions, wherein the plurality of second protrusions are arranged at intervals in the second direction, each of the second protrusions extends in the first direction, wherein all second openings are located above the second area;
removing the second sacrificial layer exposed in the second openings to form the plurality of second trenches in the second sacrificial layer, wherein the second trench exposes part of the first sacrificial layer;
removing part of the first sacrificial layer exposed in the second trenches to form the plurality of third trenches arranged at intervals in each of the first sacrificial layers; and
removing the second photoresist layer and the second sacrificial layer located on the mask layer.

7. The method for manufacturing a semiconductor structure of claim 6, wherein the forming the support structures in the filling area comprises:
forming an insulating layer in the filling area, wherein the insulating layer extends out of the filling area and covers top surfaces of the strips and the second sacrificial layer; and
removing the insulating layer located on the top surfaces of the strips and the second sacrificial layer, and removing part thickness of the mask layer, wherein the insulating layer retained in the filling area constitutes the support structures.

8. The method for manufacturing a semiconductor structure of claim 7, wherein the removing remaining first sacrificial layers and remaining second sacrificial layer located on the second area to form the plurality of columns of silicon pillar structures comprises:
forming a photoresist strip, wherein the photoresist strip is located on the first area, and extends in the first direction; and
removing the remaining first sacrificial layers and the remaining second sacrificial layer located on the second area to form the plurality of columns of silicon pillar structures.

9. The method for manufacturing a semiconductor structure of claim 1, wherein the forming a capacitor structure surrounding each of the silicon pillars comprises:
forming sequentially a first electrode layer, a dielectric layer, and a second electrode layer surrounding the silicon pillar on each of the silicon pillars exposed, wherein there is a first gap between any adjacent second electrode layers, and the dielectric layer has a high dielectric constant.

10. The method for manufacturing a semiconductor structure of claim 9, further comprising: after the forming the capacitor structure surrounding each of the silicon pillars,
forming a first interconnection layer, wherein the first interconnection layer wraps all capacitor structures and fills up the first gap;
removing part of the first interconnection layer and part of the capacitor structure to expose an upper surface of the silicon pillar located on an uppermost layer;
removing the support structures;
forming an epitaxial layer on a surface of the silicon pillar exposed, wherein the epitaxial layer defines a second gap between adjacent capacitor structures; and
forming a second interconnection layer filling up the second gap and being connected to the first interconnection layer.

11. The method for manufacturing a semiconductor structure of claim 10, further comprising: after the forming the epitaxial layer on the surface of the silicon pillar exposed, and before the forming the second interconnection layer filling up the second gap and being connected to the first interconnection layer,
oxidizing the epitaxial layer, so as to form an oxide layer on a surface of the epitaxial layer, wherein the oxide layer is configured to realize electrical insulation between adjacent capacitor structures.

12. The method for manufacturing a semiconductor structure of claim 11, wherein a thickness of the oxide layer is greater than a thickness of the first electrode layer, and is less than a sum of thicknesses of the first electrode layer and the dielectric layer.

13. The method for manufacturing a semiconductor structure of claim 11, further comprising: after forming the second interconnection layer,
removing a first sacrificial layer located in the stack structure on the first area; and
forming an active pillar in a silicon layer located on the first area by a plasma doping process, wherein the active pillar comprises a channel and a source and a drain located on either side of the channel.

14. The method for manufacturing a semiconductor structure of claim 13, further comprising: after the forming the active pillar on the silicon layer located on the first area by a plasma doping process,
forming a plurality of bit lines and a plurality of word lines on the first area, wherein each of the bit lines extends in a direction perpendicular to the substrate and connects the active pillars in a same column, and each of the word lines extends in the first direction and connects the active pillars located in a same layer.

15. The method for manufacturing a semiconductor structure of claim 1, wherein the forming a stack structure on the substrate comprises:
forming initial silicon layers and first initial sacrificial layers stacked alternately on the substrate, wherein the first initial sacrificial layers are formed by an Epitaxy process, and a material of the first initial sacrificial layers comprises silicon germanium.

16. The method for manufacturing a semiconductor structure of claim 10, wherein materials of the first interconnection layer and the second interconnection layer both comprise polysilicon.

17. A semiconductor structure, obtained by the method for manufacturing a semiconductor structure of claim 1.
